(19) United States
(12) Patent Application Publication
(10) Pub. No.: US 2017/0162402 A1
(43) Pub. Date: Jun. 8, 2017

(54) METHOD OF MANUFACTURING A SEMICONDUCTOR STRUCTURE

(71) Applicant: UNITED MICROELECTRONICS CORP., HSINCHU (TW)

(72) Inventors: Fu-Shou Tsai, Keelung City (TW); Yu-Ting Li, Chiayi City (TW); Li-Chieh Hsu, Taichung City (TW); Kun-Ju Li, Tainan City (TW); Chih-Hsun Lin, Pingtung County (TW); Po-Cheng Huang, Kaohsiung City (TW); Yi-Liang Liu, Tainan City (TW); Wen-Chin Lin, Tainan City (TW)

(21) Appl. No.: 14/960,977

(22) Filed: Dec. 7, 2015

(51) Int. Cl. H01L 21/321; H01L 21/02; H01L 21/768

(52) U.S. Cl. CPC H01L 21/3212; H01L 21/7684; H01L 21/0217

(57) ABSTRACT

A method of manufacturing a semiconductor structure is provided. First, a preliminary structure is provided. The preliminary structure has a first region and a second region, and the preliminary structure comprises a plurality of features in the first region. Then, a first polish stop layer is formed on the preliminary structure. The first polish stop layer comprises a concave portion in the second region, and the concave portion defines an opening. A first overlying layer is formed on the first polish stop layer. Thereafter, a second polish stop layer is formed on the first overlying layer. The second polish stop layer has a graduated change in composition. The second polish stop layer comprises a concave portion at least partially formed in the opening. A second overlying layer is formed on the second polish stop layer.

### TECHNICAL FIELD

The disclosure relates to a method of manufacturing a semiconductor structure. More particularly, the disclosure relates to a method using an additional polish stop layer for a chemical mechanical planarization (CMP) process.

### BACKGROUND

In the manufacturing of a semiconductor device, several forming processes and several removing processes are typically included. CMP process, being one kind of the removing processes, has been widely used. However, as the structures comprising high aspect ratio features (such as fins) are developed, a desired planarization is more difficult to be obtained by the CMP process. In the regions where the high aspect ratio features are formed, the remaining layers may be thicker, while in other regions, the remaining layers may be thinner. That is, “dishing” may be caused by the CMP process. Such a dishing, even having a depth lower than 30 Å, may be disadvantageous for the following processes.

### SUMMARY

In this disclosure, a method is provided to reduce the effect of the dishing caused by the CMP process. More specifically, in the method according to embodiments of this disclosure, an additional polish stop layer for a chemical mechanical planarization (CMP) process is provided.

According to some embodiments, a method of manufacturing a semiconductor structure comprises the following steps. First, a preliminary structure is provided. The preliminary structure has a first region and a second region, and the preliminary structure comprises a plurality of features in the first region. Then, a first polish stop layer is formed on the preliminary structure. The first polish stop layer comprises a concave portion in the second region, and the concave portion defines an opening. A first overlying layer is formed on the first polish stop layer. Thereafter, a second polish stop layer is formed on the first overlying layer. The second polish stop layer has a graduated change in composition. The second polish stop layer comprises a concave portion at least partially formed in the opening. A second overlying layer is formed on the second polish stop layer.

### BRIEF DESCRIPTION OF THE DRAWINGS

FIGS. 1 to 4 schematically illustrate a semiconductor structure at various stages of manufacturing according to embodiments.

In the following detailed description, for purposes of explanation, numerous specific details are set forth in order to provide a thorough understanding of the disclosed embodiments. It will be apparent, however, that one or more embodiments may be practiced without these specific details. In other instances, well-known structures and devices are schematically shown in order to simplify the drawing.

### DETAILED DESCRIPTION

The embodiments of the method of manufacturing a semiconductor structure will be described more fully hereinafter with reference to accompanying drawings. It is noted that, for clarity, the elements in the figures may not be shown according to their real relative sizes.

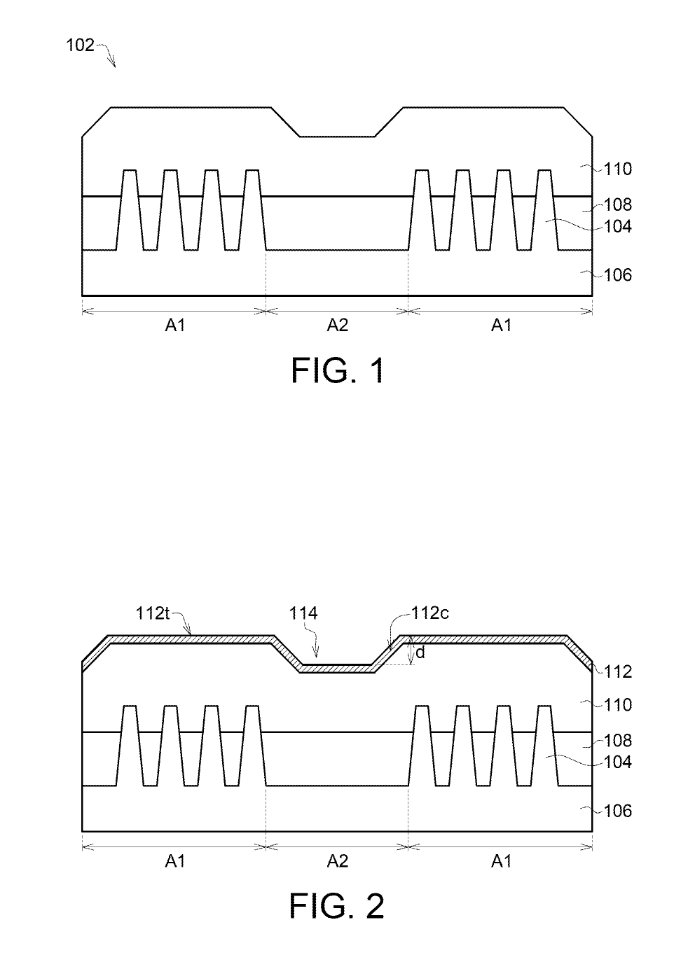

FIGS. 1 to 4 schematically illustrate a semiconductor structure at various stages of manufacturing according to embodiments. First, as shown in FIG. 1, a preliminary structure 102 is provided. The preliminary structure 102 has a first region A1 and a second region A2. The preliminary structure 102 comprises a plurality of features 104 in the first region A1. According to some embodiments, the features 104 in the first region A1 may be, but not limited to, fins. In one embodiment, the preliminary structure 102 may further comprise a substrate 106, a dielectric layer 108 and a fin-embedded layer 110. The fins are formed on the substrate 106. The dielectric layer 108 is formed on the substrate 106 between the fins. The dielectric layer 108 may be formed of oxide. The fin-embedded layer 110 is formed on the dielectric layer 108 and covers the fins. The fin-embedded layer 110 may be formed of amorphous silicon (a-Si), polycrystalline silicon, crystalline silicon, SiGe, silicide, or the like.

Then, as shown in FIG. 2, a first polish stop layer 112 is formed on the preliminary structure 102. The first polish stop layer 112 may be formed of silicon nitride, titanium nitride, tantalum nitride, or the like. The first polish stop layer 112 comprises a concave portion 112c in the second region A2. The concave portion 112c defines an opening 114. The opening 114 has a depth d.

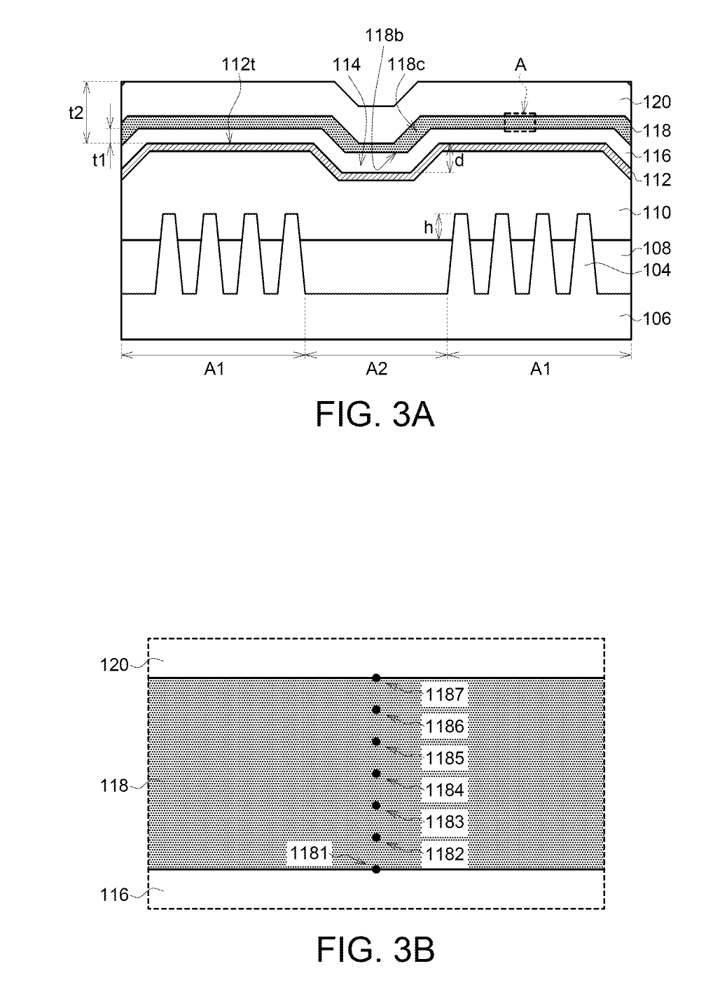

FIGS. 3A-3B schematically illustrate the semiconductor structure at the next stage, wherein FIG. 3B is an enlarged view of the region A in FIG. 3A. At this stage, a first overlying layer 116, a second polish stop layer 118 and a second overlying layer 120 are sequentially formed. The first overlying layer 116 is formed on the first polish stop layer 112. The second polish stop layer 118 is formed on the first overlying layer 116. The second overlying layer 120 is formed on the second polish stop layer 118. In some embodiments, the first overlying layer 116 and the second overlying layer 120 are formed of the same material. From another aspect of view, in these embodiments, a second polish stop layer (118) is inserted into an overlying layer (116, 120) to be removed by a following CMP process.

The first overlying layer 116 and the second overlying layer 120 may be formed of oxide. In one embodiment, the first overlying layer 116 has a thickness t1 being about a quarter of the total thickness t2 of the first overlying layer 116, the second polish stop layer 118 and the second overlying layer 120. In one embodiment, the thickness t1 is close to a height h of the portions of the features 104 that extend above the dielectric layer 108. According to some embodiments, the thickness t2 may be about 600 Å to about 3000 Å.

The second polish stop layer 118 is used as a buffer layer for the following CMP process. The second polish stop layer 118 has a graduated change in composition. Preferably, a material of the second polish stop layer 118 may be chosen according to materials of the first polish stop layer 112 as well as the first and second overlying layers 116 and 120. For example, the first polish stop layer 112 may be formed of silicon nitride, the first and second overlying layers 116 and 120 may be formed of oxide, and the second polish stop layer 118 may be formed of silicon oxynitride. As such, a better buffer effect can be provided.

Further, a composition of the second polish stop layer 118 at an interface of the second polish stop layer 118 and the first overlying layer 116 (such as at point 1181) may be closer to a composition of the first overlying layer 116 than a composition of the second polish stop layer 118 at a middle portion of the second polish stop layer 118 (such as at point 1184), and a composition of the second polish stop layer 118 at an interface of the second polish stop layer 118 and the second overlying layer 120 (such as at point 1187) may be closer to a composition of the second overlying layer 120 than the composition of the second polish stop layer 118 at the middle portion of the second polish stop layer 118 (such as at point 1184). For example, at points 1181-1187, the ratio of silicon oxide:silicon nitride in the second polish stop layer 118 formed of silicon oxynitride may be 3:1, 2:1, 1:1, 1:2, 1:1, 2:1 and 3:1, respectively. By such composition arrangement, better interfaces between the second polish stop layer 118 and the first overlying layer 116 as well as between the second polish stop layer 118 and the second overlying layer 120 can be provided.

The second polish stop layer 118 comprises a concave portion 118c at least partially formed in the opening 114, so as to provide the buffer effect during the following CMP process. For example, the second polish stop layer 118 may have a bottom surface 118b in the second region A2 lower than a top surface 112t of the first polish stop layer 112 in the first region A1. Further, in this disclosure, even only the bottom surface 118b in the second region A2 “touches” the opening 114, it is still seen that the concave portion 118c of the second polish stop layer 118 is partially formed in the opening 114. One example is that the thickness t1 of the first overlying layer 116 is substantially equal to the depth d of the opening 114. It is to be noted that the second polish stop layer 118 should not directly contact the first polish stop layer 112 (i.e., the thickness t1 of the first overlying layer 116 being zero) since the second polish stop layer 118 cannot properly provide the buffer effect in such case.

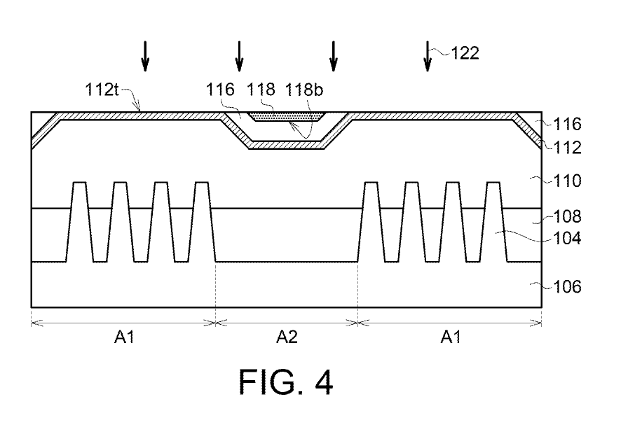

Thereafter, as shown in FIG. 4, a CMP process as indicated by arrows 122 may be performed, such that the second overlying layer 120 and the first overlying layer 116 in the first region A1 are completely removed. Here, due to the portion of the second polish stop layer 118 formed in the openings 114 in the second region A2, a dishing may not be caused by the CMP process.

In summary, in the method according to embodiments of this disclosure, an additional polish stop layer (i.e., the second polish stop layer 118) is provided, and particularly may be inserted into the layer to be removed by a following CMP process. The additional polish stop layer can have a buffer effect in the following CMP process. As such, the effect of the dishing caused by the CMP process, which is generally formed in a structure comprising high aspect ratio features, can be reduced. Following processes, such as a lithography process, can be conducted without pattern deformation.

It will be apparent to those skilled in the art that various modifications and variations can be made to the disclosed embodiments. It is intended that the specification and examples be considered as exemplary only, with a true scope of the disclosure being indicated by the following claims and their equivalents.

1. A method of manufacturing a semiconductor structure, comprising:
providing a preliminary structure, wherein the preliminary structure has a first region and a second region, and the preliminary structure comprises a plurality of features in the first region;
forming a first polish stop layer on the preliminary structure, wherein the first polish stop layer comprises a concave portion in the second region, and the concave portion defines an opening;
forming a first overlying layer on the first polish stop layer;
forming a second polish stop layer on the first overlying layer, wherein the second polish stop layer is formed of silicon oxynitride and has a graduated change in a molar ratio of silicon oxide and silicon nitride, and the second polish stop layer comprises a concave portion at least partially formed in the opening;
forming a second overlying layer on the second polish stop layer; and
performing a CMP process such that the second overlying layer and the first overlying layer in the first region are completely removed.

2. The method according to claim 1, wherein the second polish stop layer has a bottom surface in the second region lower than a top surface of the first polish stop layer in the first region.

3. The method according to claim 1, wherein the first overlying layer and the second overlying layer are formed of a same material.

4. The method according to claim 1, wherein a material of the second polish stop layer is chosen according to materials of the first polish stop layer as well as the first and second overlying layers.

5. The method according to claim 1, wherein the first polish stop layer is formed of silicon nitride, and the first and second overlying layers are formed of oxide.

6. The method according to claim 1, wherein a molar ratio of silicon oxide and silicon nitride of the second polish stop layer at an interface of the second polish stop layer and the first overlying layer is closer to a molar ratio of silicon oxide and silicon nitride of the first overlying layer than a molar ratio of silicon oxide and silicon nitride of the second polish stop layer at a middle portion of the second polish stop layer, and a molar ratio of silicon oxide and silicon nitride of the second polish stop layer at an interface of the second polish stop layer and the second overlying layer is closer to a molar ratio of silicon oxide and silicon nitride of the second overlying layer than the molar ratio of silicon oxide and silicon nitride of the second polish stop layer at the middle portion of the second polish stop layer.

7. The method according to claim 1, wherein the first overlying layer has a thickness substantially equal to a depth of the opening.

8. (canceled)

9. The method according to claim 1, wherein the features in the first region are fins.

10. The method according to claim 9, wherein the preliminary structure further comprises:
a substrate, wherein the fins are formed on the substrate;
a dielectric layer formed on the substrate between the fins; and
a fin-embedded layer formed on the dielectric layer, the fin-embedded layer covering the fins.
